(19) United States
(12) Patent Application Publication
(10) Pub. No.: US 2007/0004140 A1
(43) Pub. Date: Jan. 4, 2007

(54) Method of manufacturing a non-volatile semiconductor memory device

(75) Inventors: Dae-Hyun Jang, Seoul (KR); Jae-Seung Hwang, Suwon-si (KR); Dae-Youp Lee, Gunpo-si (KR); Sung-Un Kwon, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/475,153

(22) Filed: Jun. 27, 2006

(30) Foreign Application Priority Data
Jun. 29, 2005 (KR) 2005-56643

(51) Int. Cl. H01L 21/336; H01L 29/76

(52) U.S. Cl. 438/257; 257/314

(57) ABSTRACT

In a method of manufacturing a non-volatile semiconductor memory device that includes a first region having a first gate structure and a second region having a second gate structure, the first gate structure may include a tunnel oxide layer pattern, a first conductive layer pattern, a dielectric layer pattern and a second conductive layer pattern. A first photoresist pattern may be formed on the second conductive layer pattern to form a source line which may be formed in a region of the first area by implanting impurities. A second photoresist pattern may be formed on a hard mask layer in the second region of the substrate to form a hard mask pattern on a third conductive layer. The second gate structure having substantially vertical sidewalls may be formed in the second area by etching the third conductive layer using the hard mask pattern.

### PRIORITY STATEMENT

This application claims priority under 35 USC § 119 to Korean Patent Application No. 2005-56643 filed on Jun. 29, 2005, the entire contents of which are incorporated herein by reference.

### BACKGROUND OF THE INVENTION

1. Field of the Invention

Example embodiments of the present invention relate to a method of manufacturing a non-volatile semiconductor memory device. More particularly, example embodiments of the present invention relate to a method of manufacturing a non-volatile semiconductor memory device including a gate structure that has substantially vertical sidewalls.

2. Description of the Related Art

Semiconductor memory devices are generally divided into volatile semiconductor memory devices, for example, dynamic random access memory (DRAM) devices or static random access memory (SRAM) devices, and non-volatile semiconductor memory devices, for example, erasable programmable read only memory (EPROM) devices, electrically erasable programmable read only memory (EEPROM) devices or flash memory devices. The volatile semiconductor memory device may lose data stored therein when power to the volatile semiconductor device is off, whereas the non-volatile semiconductor memory device maintains data stored therein even if power to the non-volatile semiconductor memory device is off.

In a flash memory device, data may be electrically programmed into or erased out of unit cells of the flash memory device by a Fowler-Nordheim (F-N) tunneling method and/or a channel hot electron injection method. The flash memory device may have a first gate structure in a cell area and a high voltage metal oxide semiconductor (MOS) transistor in a peripheral circuit area. The first gate structure may include a tunnel oxide layer, a floating gate, a dielectric layer and a control gate. The high voltage MOS transistor may have a second gate structure that may include a gate insulation layer and a gate electrode.

As a flash memory device has become highly integrated, the flash memory device may not rapidly operate under a minute voltage because resistances of conductive wirings in the flash memory device may increase. Accordingly, metal silicide layers may be used in a first gate structure and a second gate structure to reduce resistances of the first and the second gate structures. For example, tungsten silicide layers may be employed in the first and the second gate structures. Further, cobalt silicide layers may be used in the first and the second gate structures because cobalt silicide has a specific resistance lower than that of tungsten silicide.

In a conventional method for forming cobalt silicide layers in a flash memory device, the cobalt silicide layers may be formed on polysilicon layer patterns of first and second gate structures by a silicidation process after the polysilicon layer patterns of the first and the second gate structures are exposed. Accordingly, in the conventional method, hard mask patterns do not exist on the polysilicon layer patterns because the polysilicon layers are exposed to form the cobalt silicide layers thereon. If the polysilicon layer patterns are formed using the hard mask patterns formed thereon, the hard mask patterns should be completely removed from the polysilicon layers prior to forming the cobalt silicide layers according to the conventional method. However, an isolation layer and a tunnel oxide layer may be etched in an etching process for removing the hard mask patterns, which may cause an electrical failure due to etched damages to the isolation layer and the tunnel oxide layer in the flash memory.

In light of the above-mentioned problem, polysilicon layer patterns of a flash memory device are formed using photoresist patterns if cobalt silicide layers are to be formed on the polysilicon layer patterns according to another conventional method. However, etched by-products may be attached to sidewalls of the polysilicon layer patterns in an etching process for forming the polysilicon layer patterns when the photoresist patterns are employed as etching masks. As a result, the polysilicon layer patterns may have lower portions wider than upper portions thereof because etched by-products are attached to the lower portions of the polysilicon layer patterns. Accordingly, gate structures including the polysilicon layer patterns may have sidewalls inclined at angles.

FIG. 1 is a cross-sectional view illustrating a conventional gate structure including a polysilicon layer pattern having an inclined sidewall.

As shown in FIG. 1, a conventional gate structure may include a gate insulation layer 12 formed on a substrate 10 having an isolation layer 20, a polysilicon layer pattern 14 that may be formed on the gate insulation layer 12, and a spacer 16 that may be formed on an inclined sidewall of the polysilicon layer pattern 14. If a spacer 16 is formed on a polysilicon layer pattern 14 having an inclined sidewall, the spacer 16 may have a width reduced by Δd that corresponds to an increased width of the polysilicon layer pattern 14 after a conventional etching process for forming the polysilicon layer pattern 14 using a photoresist pattern as an etching mask is performed. Because source/drain regions 18 may extend beneath the spacer 16, the source/drain regions 18 may have reduced widths due at least in part to a decrease of the width of the spacer 16. If source/drain regions 18 have a reduced width, a MOS transistor including the gate structure and the source/drain regions may have a low breakdown voltage, which may cause an electrical failure of a flash memory device having the MOS transistor.

### SUMMARY OF THE INVENTION

Example embodiments of the present invention provide a method of manufacturing a non-volatile semiconductor memory device including a gate structure having substantially vertical sidewalls, which may prevent an electrical failure of the non-volatile semiconductor memory device.

An example embodiment of the present invention provides a method of manufacturing a non-volatile semiconductor memory device. In the method of manufacturing the non-volatile semiconductor memory device, a tunnel insulation layer, a preliminary first conductive layer pattern, a dielectric layer and a second conductive layer may be sequentially formed on a first area of a substrate. A gate insulation layer, a third conductive layer and a hard mask layer may be sequentially formed on a second area of the substrate. A first gate structure having a tunnel oxide layer pattern, a first conductive layer pattern, a dielectric layer pattern and a second conductive layer pattern may be formed on the first area by etching the second conductive layer, the dielectric layer, the preliminary first conductive layer pattern and the tunnel oxide layer. A first photoresist pattern may be formed on the second conductive layer pattern. The first photoresist pattern may expose a portion of the first area. A second photoresist pattern may be formed on the hard mask layer. A hard mask pattern may be formed on the third conductive layer by etching the hard mask layer using the second photoresist pattern as an etching mask. A source line may be formed at the exposed portion of the first area by implanting impurities using the first photoresist pattern as a mask. A second gate structure having substantially vertical sidewalls may be formed on the second area by etching the third conductive layer using the hard mask pattern as an etching mask.

In an example embodiment of the present invention, a tunnel insulation layer, a preliminary first conductive layer pattern, a dielectric layer, and a second conductive layer in the first area may be simultaneously formed with a gate insulation layer, a third conductive layer and a hard mask layer in a second area During formation of the tunnel insulation layer, the preliminary first conductive layer pattern, the dielectric layer and the second conductive layer in the first area, and during formation of the gate insulation layer, the third conductive layer and the hard mask layer in the second area, a preliminary tunnel insulation layer, a preliminary first conductive layer, a preliminary dielectric layer and a preliminary second conductive layer may be sequentially formed on the first and the second areas of the substrate. The tunnel insulation layer, the preliminary first conductive layer pattern, the dielectric layer and the second conductive layer may be formed on the first area by selectively etching portions of the preliminary tunnel insulation layer, the preliminary first conductive layer, the preliminary dielectric layer and the preliminary second conductive layer, respectively, on the second area A preliminary gate insulation layer, a preliminary third conductive layer and a preliminary hard mask layer may be formed on the second conductive layer and on the second area. Then, the gate insulation layer, the third conductive layer and the hard mask layer may be formed on the second area by selectively etching portions of the preliminary gate insulation layer, the preliminary third conductive layer and the preliminary hard mask layer positioned on the second conductive layer, respectively.

In an example embodiment of the present invention, the second conductive layer pattern and the third conductive layer may include polysilicon.

In an example embodiment of the present invention, the first area may correspond to a cell area of a non-volatile semiconductor memory device and the second area may correspond to a peripheral circuit area of the non-volatile semiconductor memory device.

In an example embodiment of the present invention, an isolation layer having a line shape may be formed on the first area. The isolation layer may extend along a direction substantially perpendicular to the second conductive layer pattern. Before forming a source line, a portion of the isolation layer exposed by the first photoresist pattern may be removed. The portion of the isolation layer may be removed while forming a hard mask pattern.

In an example embodiment of the present invention, an additional hard mask layer and an anti-reflective layer may be formed beneath the first and the second photoresist patterns. The additional hard mask layer may include amorphous silicon.

In an example embodiment of the present invention, a third photoresist pattern may be formed on the second conductive layer pattern to entirely cover the first area after forming the hard mask pattern.

In an example embodiment of the present invention, after the hard mask pattern remaining on the second gate structure is removed, spacers may be formed on sidewalls of the first and the second gate structures. Then, metal silicide patterns may be formed on the first gate structure, the second gate structure and the substrate. The hard mask pattern may be removed by a wet etching process using an etching solution that includes a hydrogen peroxide solution and an ammonia solution. The hard mask pattern may be removed after forming the third photoresist pattern. The spacers may have thickness of about 300 to about 2,000 Å. Before forming the spacers, first doping regions having low impurity concentrations may be formed at portions of the second area adjacent to the second gate structure, and then the third photoresist pattern may be removed. The metal silicide patterns may include cobalt silicide, tungsten silicide, titanium silicide and/or tantalum silicide.

In an example embodiment of the present invention, the metal silicide patterns may be formed by forming a metal layer on the first gate structure, the second gate structure, the spacers and the substrate; forming the metal silicide patterns on the first gate structure, the second gate structure and the substrate in accordance with reaction metal in the metal layer and silicon in the first gate structure, the second gate structure and the substrate through at least one thermal treatment process; and removing portions of the metal layer positioned on the spacers.

In an example embodiment of the present invention, the metal silicide patterns may be formed by a first thermal treatment process at a first temperature and a second thermal treatment process at a second temperature substantially higher than the first temperature.

In an example embodiment of the present invention, the tunnel insulation layer and the gate insulation layer may include silicon oxide. The tunnel insulation layer may have a thickness different from a thickness of the gate insulation layer.

According to example embodiments of the present invention, an MOS transistor in a peripheral circuit area of a non-volatile semiconductor memory device may include a gate structure that has substantially vertical sidewalls through a relatively simple manufacturing process. Accordingly, the MOS transistor in the peripheral circuit area may have an enhanced breakdown voltage.

Further, according to example embodiments of the present invention, a MOS transistor in the peripheral circuit area may have improved response speed because a metal silicide pattern having a low resistance may be formed on the gate structure and source/drain regions of the MOS transistor in the peripheral circuit area.

### BRIEF DESCRIPTION OF THE DRAWINGS

Example embodiments of the present invention will be more clearly understood from the detailed description taken in conjunction with the accompanying drawings in which:

FIG. 1 is a cross-sectional view illustrating a conventional gate structure including a polysilicon layer pattern having an inclined sidewall;

FIGS. 2 to 14 are cross-sectional views illustrating a method of manufacturing a non-volatile semiconductor memory device in accordance with an example embodiment of the present invention; and

FIG. 15 is a plan view illustrating a non-volatile semiconductor memory device in accordance with an example embodiment of the present invention.

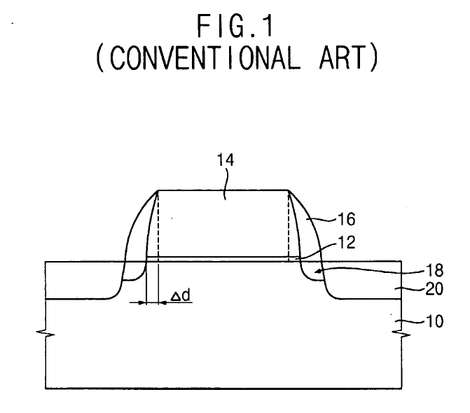

### DESCRIPTION OF EXAMPLE EMBODIMENTS OF THE PRESENT INVENTION

The present invention is described more fully hereinafter with reference to the accompanying drawings, in which example embodiments of the present invention are shown. The present invention may, however, be embodied in many different forms and should not be construed as limited to the embodiments set forth herein. Rather, these example embodiments are provided so that this disclosure will be thorough and complete, and will fully convey the scope of the present invention to those skilled in the art. In the drawings, the sizes and/or relative sizes of layers and/or regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

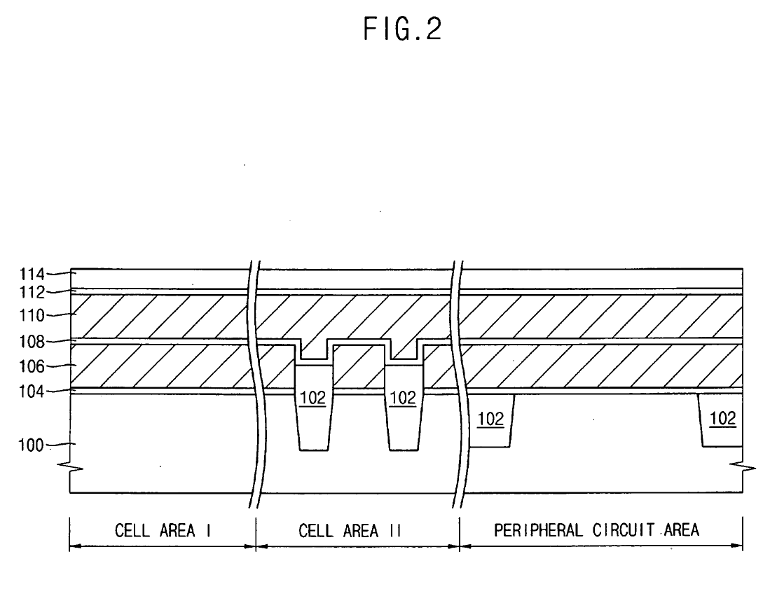

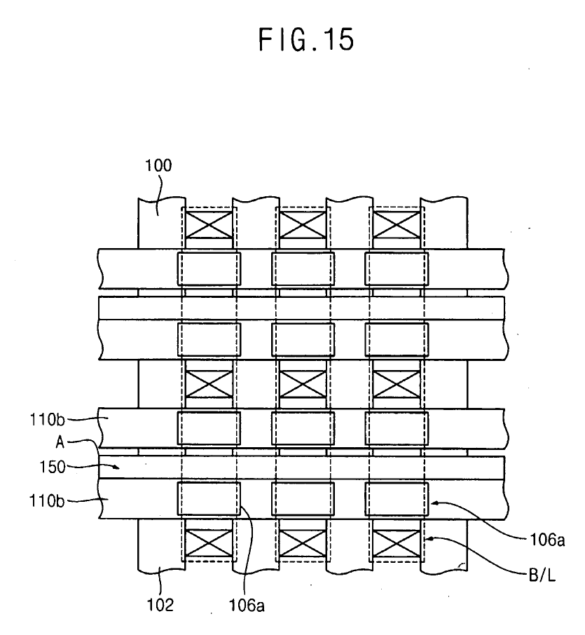

FIGS. 2 to 15 are cross-sectional views illustrating a method of manufacturing a non-volatile semiconductor memory device in accordance with an example embodiment of the present invention. In an example embodiment of the present invention as shown in FIGS. 2 to 14, “cell area I” indicates a cross-section of a non-volatile semiconductor device along a first direction, whereas “cell area II” represents a cross-section of the non-volatile semiconductor memory device in a second direction substantially perpendicular to the first direction. For example, the first direction and the second direction may correspond to an X-direction and a Y-direction in X-Y coordinates. FIG. 15 is a plane view illustrating a non-volatile semiconductor memory device in accordance with an example embodiment of the present invention.

Referring to an example embodiment of the present invention as shown in FIG. 2, a semiconductor substrate 100, which may have a cell area and/or a peripheral circuit area is provided. Unit cells of a non-volatile semiconductor memory device may be formed in the cell area, and peripheral circuits for driving the unit cells may be positioned in the peripheral circuit area.

A pad oxide layer (not shown) may be formed on a semiconductor substrate 100 including a cell area and a peripheral circuit area. The pad oxide layer may be formed by a thermal oxidation process and/or a chemical vapor deposition (CVD) process. The pad oxide layer may have a thickness of about 70 to about 100 Å measured from an upper face of the semiconductor substrate 100.

A first hard mask layer (not shown) may be formed on the pad oxide layer. The first hard mask layer may be formed using a nitride, for example, silicon nitride, etc. The first hard mask layer may be formed by a low pressure chemical vapor deposition (LPCVD) process and/or a plasma enhanced chemical vapor deposition (PECVD) process. For example, the first hard mask layer may be formed using an SiH₂Cl₂ gas, an SiH₄ gas and an NH₃ gas. In an example embodiment of the present invention, a first hard mask layer may have a height substantially greater than a height of a floating gate in a non-volatile semiconductor memory device.

According to an example embodiment of the present invention, a first hard mask layer and a pad oxide layer may be partially etched through a photolithography process, thereby sequentially forming a pad oxide layer pattern and a first hard mask pattern on the semiconductor substrate 100.

The semiconductor substrate 100 may be partially etched using the first hard mask pattern as an etching mask to form trenches at upper portions of the semiconductor substrate 100. Trenches positioned in a cell area may be extended along the first direction.

Inner oxide layers (not shown) may be formed on sidewalls and bottom faces of the trenches. The inner oxide layers may be formed by a thermal oxidation process and/or a CVD process. The inner oxide layers may cure damage to the semiconductor substrate 100 generated, for example, during the etching process for forming the trenches. The inner oxide layers may also prevent a leakage current generated through the trenches.

In an example embodiment of the present invention, nitride liners may be formed on the inner oxide layers and may prevent impurities generated in successive processes from diffusing into isolation layer patterns 102, which may be formed in the trenches and the semiconductor substrate 100.

An isolation layer may be formed on the first hard mask pattern to substantially fill the trenches. The isolation layer may be formed using an oxide, for example, silicon oxide. The isolation layer may be formed by a CVD process, a PECVD process, an atomic layer deposition (ALD) process, etc.

The isolation layer may be partially removed by a chemical mechanical polishing (CMP) process and/or an etch back process until the first hard mask pattern is exposed. Thus, the isolation layer patterns 102 may be formed in the trenches, respectively. Further, the isolation layer patterns 102 positioned in the cell area may be prolonged in the first direction.

The first hard mask pattern and the pad oxide layer pattern may be removed from the semiconductor substrate 100. The first hard mask pattern and the pad oxide layer pattern may be removed by a wet etching process, for example. When the first hard mask pattern and the pad oxide layer pattern are removed, first openings may be formed between the isolation layer patterns 102. Floating gates of the non-volatile semiconductor memory device may be positioned in the first openings. The first openings may be extended along the first direction because the first openings may be positioned between the isolation layer patterns 102 extended in the first direction.

A preliminary tunnel insulation layer 104 may be formed on portions of the semiconductor substrate 100, which may be exposed through the first openings. The preliminary tunnel insulation layer 104 may be formed using an oxide, for example, silicon oxide. Alternatively, the preliminary tunnel insulation layer 104 may be formed using a material that has a high dielectric constant, for example, hafnium oxide, titanium oxide, aluminum oxide, silicon nitride, zirconium oxide, tantalum oxide, etc. The preliminary tunnel insulation layer 104 may be formed by a radical oxidation process, a thermal oxidation process, a CVD process, an ALD process, a high density plasma chemical vapor deposition (HDP-CVD) process, etc.

A preliminary first conductive layer may be formed on the preliminary tunnel insulation layer 104 and/or the isolation layer patterns 102 to sufficiently fill the first openings. The preliminary first conductive layer may be patterned to form floating gates. The preliminary first conductive layer may be formed using polysilicon doped with impurities by an LPCVD process, for example. The impurities may be doped in the preliminary first conductive layer by an in-situ doping process.

In an example embodiment of the present invention, the preliminary first conductive layer may be formed on sidewalls and bottom faces of the first openings. The floating gates may have, for example, “U” shapes by patterning the preliminary first conductive layer.

The preliminary first conductive layer may be partially removed by a CMP process and/or an etch back process until the isolation layer patterns 102 are exposed to form a first conductive layer 106 on the preliminary tunnel insulation layer 104. The first conductive layer 106 may have a line shape extending in the first direction.

Upper portions of the isolation layer patterns 102 may be partially removed to expose an upper sidewall of the first conductive layer 106. The upper portions of the isolation layer patterns 102 may be removed by a wet etching process, for example.

A preliminary dielectric layer 108 may be formed on the first conductive layer 106 and/or the isolation layer patterns 102. The preliminary dielectric layer 108 may be formed using, for example, oxide, nitride, a high-k material, etc. Alternatively, the preliminary dielectric layer 108 may have an oxide/nitride/oxide (ONO) structure in which a lower oxide film, a nitride film and/or an upper oxide film may be sequentially formed.

A preliminary second conductive layer 110, which may be used for a control gate of the non-volatile semiconductor memory device may be formed on the preliminary dielectric layer 108. The preliminary second conductive layer 110 may be formed using polysilicon doped with impurities by an LPCVD process, for example. The impurities may be doped into the preliminary second conductive layer 110 by an in-situ doping process.

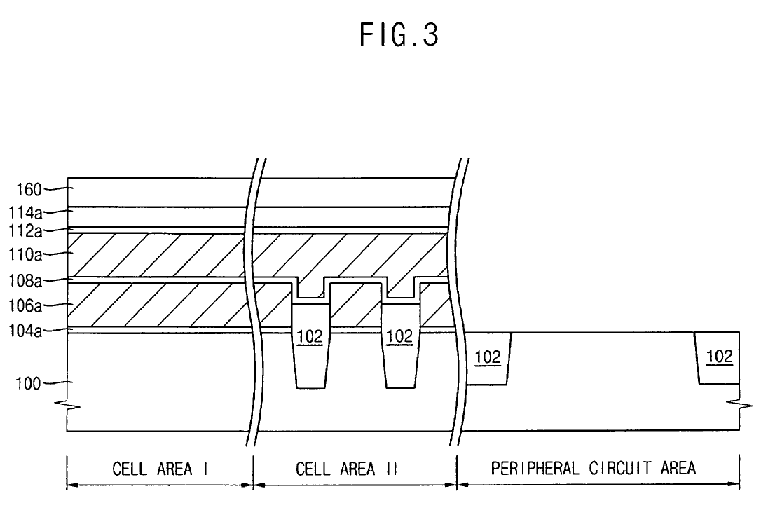

A buffer oxide layer 112 and/or a nitride layer 114 may be formed on the preliminary second conductive layer 110. The buffer oxide layer 112 may reduce a stress generated between the preliminary second conductive layer 110 and the nitride layer 114. The buffer oxide layer 112 may be formed by, for example, a CVD process, an LPCVD process, a PECVD process, an HDP-CVD process, etc. The nitride layer 114 may be formed using, for example, silicon nitride by a CVD process, an LPCVD process and/or a PECVD process. The nitride layer 114 may be used in an etching process for selectively etching a third conductive layer 116 (see FIG. 3) successively formed.

Referring to an example embodiment of the present invention as shown in FIG. 3, a resultant structure as described above formed in the peripheral circuit area may be selectively removed to expose the peripheral circuit area of the semiconductor substrate 100.

For example, after a first photoresist film (not shown) is formed on the nitride layer 114, the first photoresist film may be exposed and developed to form a first photoresist pattern 160 over the cell area of the semiconductor substrate 100. Accordingly, the resultant structure in the peripheral circuit area may be exposed when the first photoresist pattern is exposed. Using the first photoresist pattern 160 as an etching mask, portions of the nitride layer 114, the buffer oxide layer 112, the preliminary second conductive layer 110, the preliminary dielectric layer 108, the first conductive layer 106 and the preliminary tunnel insulation layer 104 in the peripheral circuit area may be etched to expose the peripheral circuit area of the semiconductor substrate 100.

A tunnel insulation layer 104a, a preliminary first conductive layer pattern 106a, a dielectric layer 108a, a second conductive layer 110a, a buffer oxide layer pattern 112a and a nitride layer pattern 114a may be formed in the cell area because the first photoresist pattern 160 may protect portions of the nitride layer 114, the buffer oxide layer 112, the preliminary second conductive layer 110, the preliminary dielectric layer 108, the first conductive layer 106 and the preliminary tunnel insulation layer 104 in the cell area

The first photoresist pattern 160 may be removed from the nitride layer pattern 114a by an ashing process and/or a stripping process.

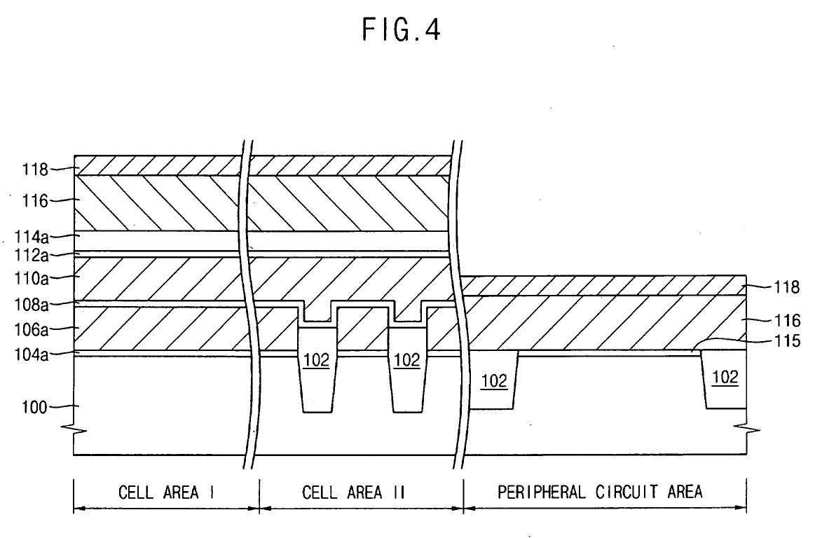

Referring to an example embodiment of the present invention as shown in FIG. 4, a gate insulation layer 115 may be selectively formed on the exposed peripheral circuit area of the semiconductor substrate 100. The gate insulation layer 115 may be formed by, for example, a thermal oxidation process and/or a CVD process. The gate insulation layer 115 may include an oxide, for example, silicon oxide, etc. When the gate insulation layer 115 is formed by the thermal oxidation process, the gate insulation layer 115 may be formed only on the peripheral circuit area except for the cell area because the nitride layer pattern 114a may be positioned over the cell area. The gate insulation layer 115 may have a thickness substantially different from that of the tunnel insulation layer 104a.

Peripheral circuits for driving the unit cells may be positioned on the peripheral circuit area. Accordingly, a high voltage MOS transistor of the non-volatile semiconductor memory device may be formed in the peripheral circuit area to drive the unit cells of the non-volatile semiconductor device. In the high voltage MOS transistor, the gate insulation layer 115 may have a thickness sufficient to prevent a breakdown of the MOS transistor because high voltages may be applied to a gate electrode and/or source/drain regions thereof. If a gate insulation layer 115 includes a material substantially the same as the material of the tunnel oxide layer 104a, the gate insulation layer 115 may be thicker than a tunnel insulation layer 104a.

A third conductive layer 116 may be formed on the gate insulation layer 115 and the nitride layer pattern 114a. The third conductive layer 116 may be patterned to form a gate electrode of the transistor positioned in the peripheral circuit area. The third conductive layer 116 may be formed, for example, by using undoped polysilicon or doped polysilicon by an LPCVD process. If the third conductive layer 116 includes undoped polysilicon, impurities may be doped into the third conductive layer 116 in a successive process for forming source/drain regions of a transistor in the peripheral circuit area.

A second hard mask layer 118 may be formed on the third conductive layer 116. The second hard mask layer 118 may be formed using, for example, silicon oxide, silicon nitride or silicon oxynitride by a CVD process. If the second hard mask layer 118 includes silicon nitride or silicon oxynitride, the second hard mask layer 118 may also serve as an anti-reflective layer (ARL) for a successive etching process.

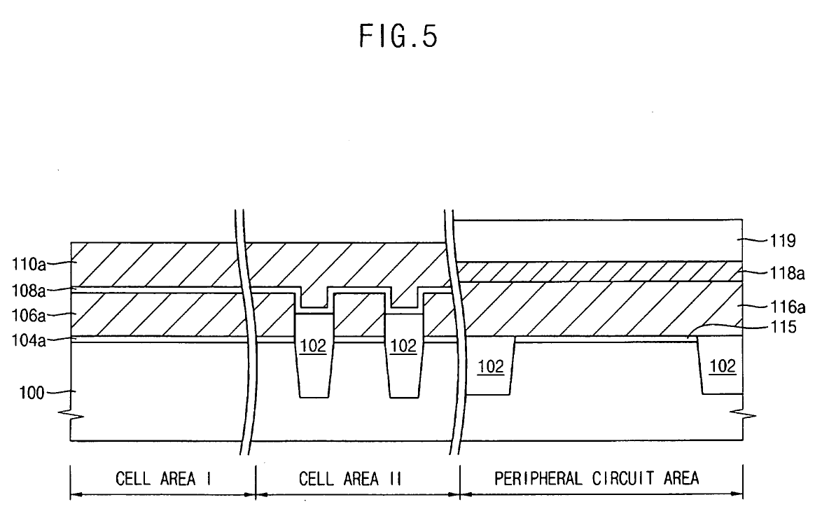

According to an example embodiment of the present invention as shown in FIG. 5, a second photoresist film may be coated on the second hard mask layer 118, and then the second photoresist film may be exposed and developed to form a second photoresist pattern 119 on the second hard mask layer 118. The second photoresist film 119 may selectively expose a portion of the second hard mask layer 118 positioned in the cell area.

Using the second photoresist pattern 119 as an etching mask, portions of the second hard mask layer 118 and the third conductive layer 116 in the cell area may be etched, and then the nitride layer pattern 114a and the buffer oxide layer pattern 112a may be sequentially etched to expose the second conductive layer 110a in the cell area.

If each of the second conductive layer 110a and the third conductive layer 116 include polysilicon, the second conductive layer 110a may be partially etched in etching the third conductive layer 116 when the nitride layer pattern 114a and the buffer oxide layer pattern 112a are not formed on the second conductive layer 110a. However, according to an example embodiment of the present invention, the third conductive layer 116 may be completely etched in the cell area without substantially any consumption of the second conductive layer 110a because the buffer oxide layer pattern 112a may be positioned on the second conductive layer 110a. After a portion of the third conductive layer 116 in the cell area is etched using the nitride layer pattern 114a as an etching stop layer, the nitride layer pattern 114a and the buffer oxide layer pattern 112a may be removed without causing substantially any consumption of the second conductive layer 110a.

After performing the above-described etching process according to an example embodiment of the present invention, a preliminary third conductive layer pattern 116a and a preliminary second hard mask pattern 118a may remain in the peripheral circuit area.

The second photoresist pattern 119 may be removed from the preliminary second hard mask pattern 118a by an ashing process and/or a stripping process.

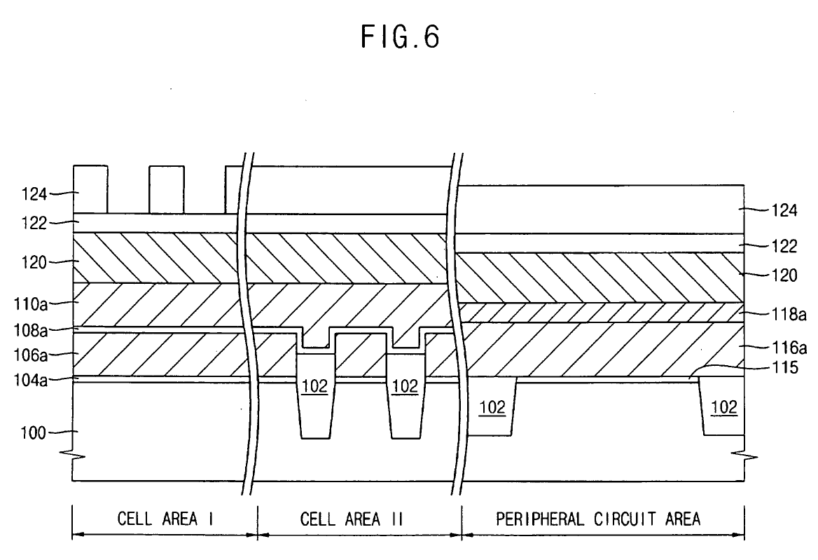

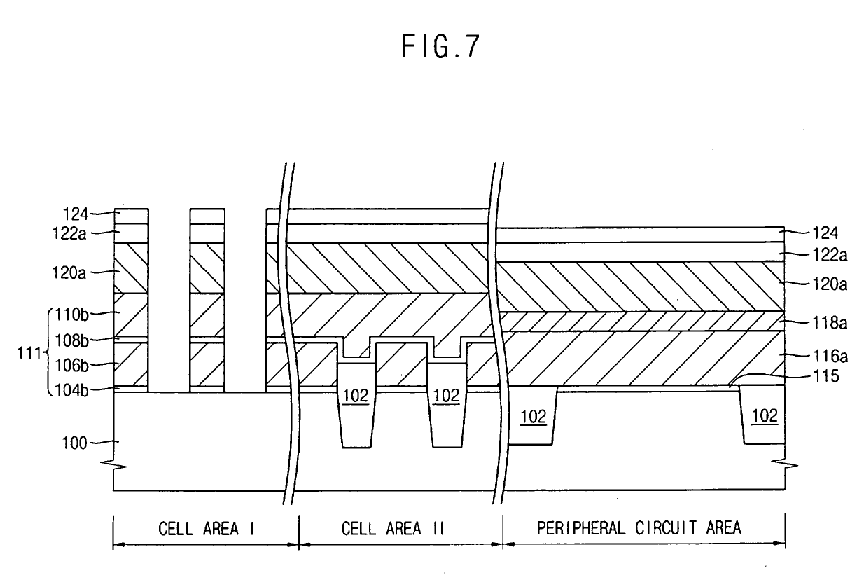

According to an example embodiment of the present invention as shown in FIG. 6, an additional mask layer 120 may be formed on the second conductive layer 110a and the preliminary third conductive layer pattern 116a. The additional mask layer 120 may be provided for forming a first gate structure 111 (see FIG. 7) in the cell area. The additional mask layer 120 may be formed, for example, by using amorphous carbon by a CVD process. If the additional mask layer 120 includes amorphous carbon, the additional mask layer 120 may be removed together with a third photoresist pattern 124 by an ashing process without any additional process for removing the additional mask layer 120 because amorphous carbon may be easily removed by the ashing process, which may use oxygen. Alternatively, in an example embodiment of the present invention, the additional hard mask layer 120 may not be formed on the second conductive layer 110a and the preliminary third conductive layer pattern 116a to further simplify the manufacturing process for the non-volatile semiconductor memory device.

An anti-reflective layer 122 may be formed on the additional hard mask layer 120. The anti-reflective layer 122 may be formed using, for example, silicon oxide and/or silicon oxynitride. Alternatively, the anti-reflective layer 122 may be formed using an organic material.

After a third photoresist film is coated on the anti-reflective layer 122, the third photoresist film may be exposed and developed to form a third photoresist pattern 124 on the anti-reflective layer 122. The third photoresist pattern 124 may completely cover the peripheral circuit area whereas the third photoresist pattern 124 may partially expose the cell area. The third photoresist pattern 124 in the cell area may have a line shape along a second direction substantially perpendicular to the first direction. The third photoresist pattern 124 may serve as an etching mask for forming the first gate structure 111 in the cell area.

A gate structure of the non-volatile semiconductor memory device may have a width of about 50 to about 90 nm. Accordingly, the third photoresist pattern 124 may have a width of about 50 to about 90 nm. For forming the third photoresist pattern 124, photoresist employed in a light having a wavelength of below about 193 nm may be required. This photoresist may be generally referred to as an argon fluoride (ArF) photoresist. If the third photoresist pattern 124 is formed using an ArF photoresist, the third photoresist pattern 124 may not have a height of above about 500 Å and also the third photoresist pattern 124 may not have a sufficient endurance in the etching process for forming the first gate structure 111. Accordingly, the additional hard mask layer 120 is formed between the third photoresist pattern 124 and the second conductive layer 10a to be etched in an example embodiment of the present invention.

Referring to FIGS. 7 and 15, the anti-reflective layer 122 and the additional hard mask layer 120 may be partially etched using the third photoresist pattern 124 as an etching mask to form an additional hard mask pattern 120a and an anti-reflective layer pattern 122a on the second conductive layer 110a and the preliminary third conductive layer pattern 118a.

The second conductive layer 110a, the dielectric layer 108a, the preliminary first conductive layer pattern 106a and the tunnel insulation layer 104a may be etched using the third photoresist pattern 124, the anti-reflective layer pattern 122a and the additional hard mask pattern 120a as etching masks. Accordingly, the first gate structure 111 may be formed in the cell area of the semiconductor substrate 100. The first gate structure 111 may include a tunnel insulation layer pattern 104b, a first conductive layer pattern 106b, a dielectric layer pattern 108b and a second conductive layer pattern 110b sequentially formed in the cell area.

The second conductive layer pattern 110b may have a line shape prolonged in the second direction substantially perpendicular to the first direction. The first conductive layer pattern 106b may have an isolated island shape because the first conductive layer 106b may be formed through twice etching the preliminary first conductive layer along the first direction and the second direction.

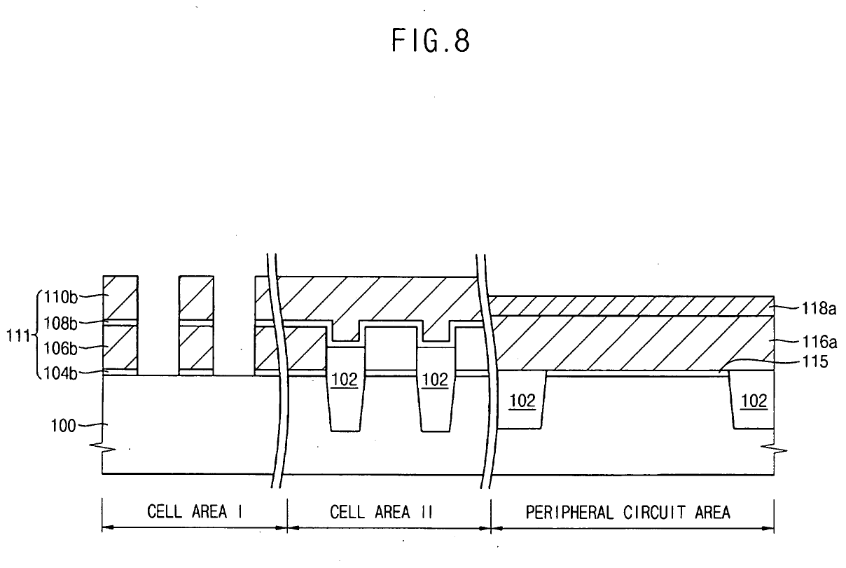

According to an example embodiment of the present invention as shown in FIG. 8, the third photoresist pattern 124 may be etched by an ashing process and/or a stripping process. If the third photoresist pattern 124 is removed by the ashing process using oxygen, the anti-reflective layer pattern 122a and the additional hard mask pattern 120a may be simultaneously removed from the first gate structure 111. When the first gate structures 111 are formed in the cell area, portions of the substrate 110 between the first gate structures 111 may be exposed.

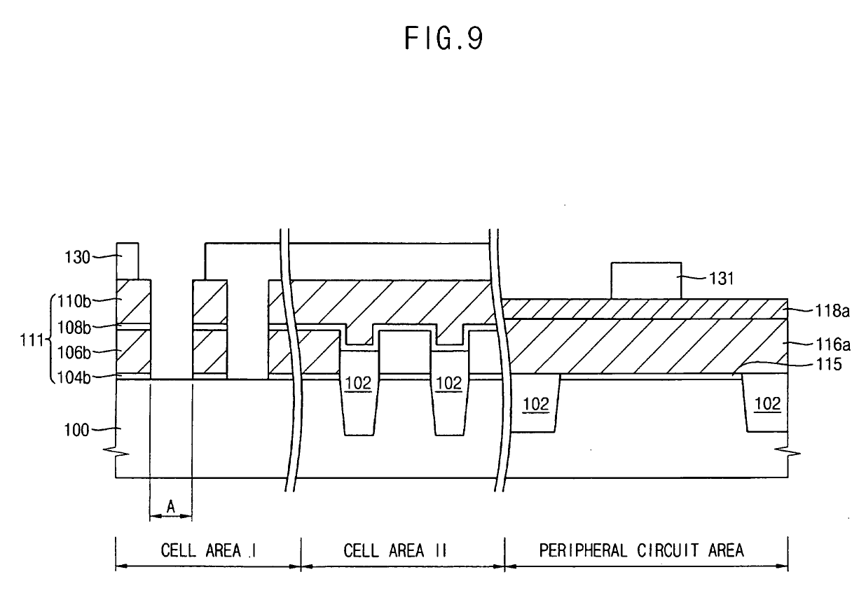

Referring to FIGS. 9 and 15, a fourth photoresist film may be coated on the first gate structures 111, the exposed portions of the substrate 100 and the second hard mask pattern 118a in the peripheral circuit area. The fourth photoresist film may be exposed and developed to form a fourth photoresist pattern 130 and a fifth photoresist pattern 131 in the cell area and the peripheral circuit area, respectively. The fourth photoresist pattern 130 may selectively expose a source line region A in the cell area. The fifth photoresist pattern 131 may selectively cover a gate electrode of the transistor positioned in the peripheral circuit area.

The source line region A may include first portions of the cell area where source regions of cell transistors may be formed and may also include second portions of the cell area between the source regions of the cell transistors along the second direction. Thus, the fourth photoresist pattern 130 may have a line shape extended along the second direction to expose the first portions of the cell area and upper portions of the isolation layer patterns 102 (e.g., the second portions of the cell area) between the source regions of the cell transistors.

The fourth photoresist pattern 130 may serve as an etching mask for selectively etching isolation layer patterns 102 in the source line region A and also an ion implantation mask for implanting impurities into the source line region A. In an example embodiment of the present invention, the isolation layer patterns 102 may be partially etched by a self alignment etching process that may utilize etching selectivity between silicon and silicon oxide, for example. The fourth photoresist pattern 130 may sufficiently expose the source line region A in the cell area.

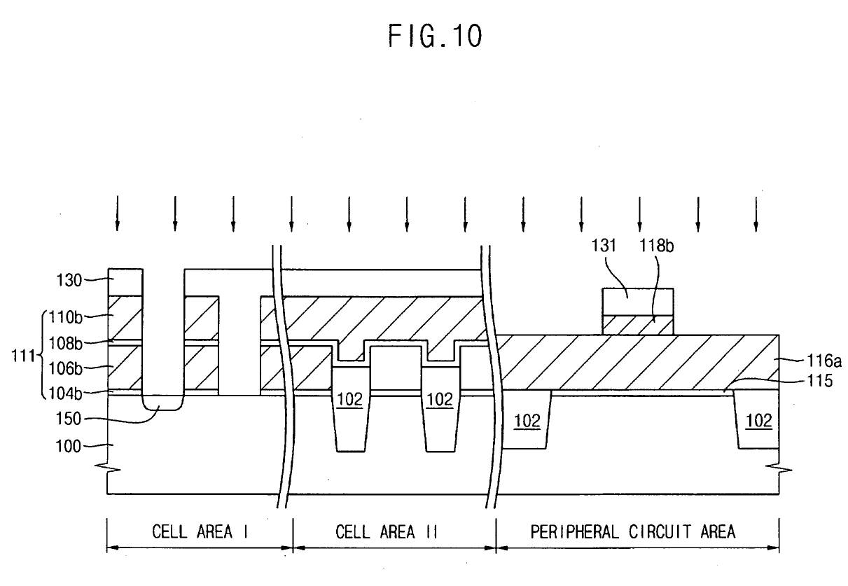

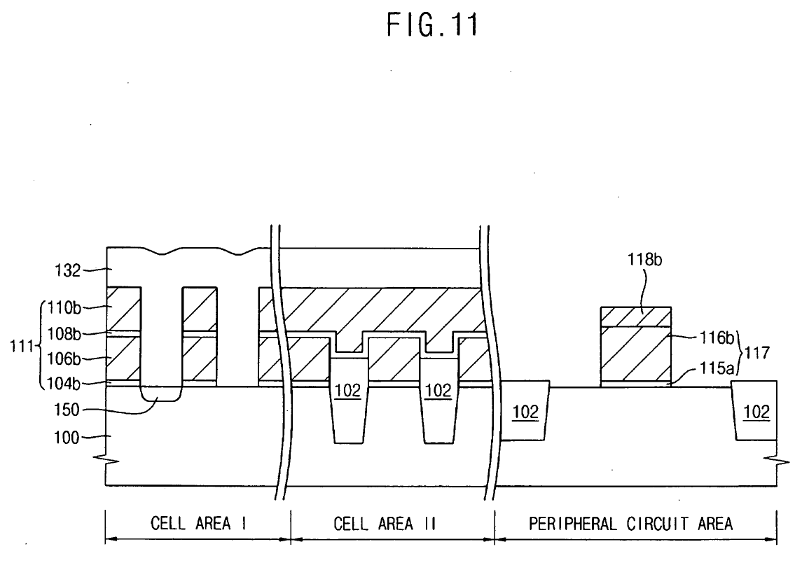

Referring to FIGS. 10 and 15, the exposed isolation layer patterns 102 in the cell area and the exposed preliminary second hard mask layer 118a in the peripheral circuit area may be substantially, simultaneously etched using the fourth and the fifth photoresist patterns 130 and 131 as etching masks. Accordingly, the source line region A may be exposed in the cell area by partially removing the isolation layer patterns 102 between the source regions of the cell transistors. A second hard mask pattern 118b for forming a second gate structure 117 (see FIG. 11) may be formed in the peripheral circuit area substantially, simultaneous with partially removing the exposed isolation layer patterns 102.

To substantially, simultaneously etch the exposed isolation layer patterns 102 and the exposed preliminary second hard mask layer 118a, the etching process may be carried out with an etching selectivity between the exposed isolation layer patterns 102 and the exposed preliminary second hard mask layer 118a by about 1.0:1.0. When the exposed isolation layer patterns 102 are etched, the semiconductor substrate 100 may be partially etched, which may cause a stepped portion in an active region of the cell area Accordingly, the exposed isolation layer patterns 102 may be etched without etching the semiconductor substrate 100. Further, the preliminary third conductive layer pattern 116a may be partially etched when the exposed preliminary second hard mask layer 118a is etched. Hence, the exposed preliminary second hard mask layer 118a may be etched without etching the preliminary third conductive layer pattern 116a.

If the isolation layer patterns 102 include silicon oxide and the preliminary second hard mask layer 118a includes silicon nitride, the exposed isolation layer patterns 102 and the exposed preliminary second hard mask layer 118a may be etched by, for example, a dry etching process that uses an etching gas including a CHF₃ gas and an oxygen gas to expose the source line region A and substantially, simultaneously forming the second hard mask pattern 118b.

Impurities may be implanted into the exposed source line region A using the fourth and the fifth photoresist patterns 130 and 131 as implantation masks as indicated using the arrows shown in FIG. 10 so that a source line 150 may be formed in the cell area.

The fourth and the fifth photoresist patterns 130 and 131 may be removed by, for example, an ashing process and/or a stripping process.

Referring to an example embodiment of the present invention as shown in FIG. 11, a fifth photoresist film may be formed to cover the cell area and the peripheral circuit area, and then the fifth photoresist film may be exposed and developed to form a sixth photoresist pattern 132 covering the cell area. The sixth photoresist pattern 132 may selectively expose the peripheral circuit area.

Using the second hard mask pattern 118b and the sixth photoresist pattern 132 as etching masks, the preliminary third conductive layer pattern 116a and the gate insulation layer 115 may be etched so that the second gate structure 117 may be formed in the peripheral circuit area. The second gate structure 117 may include a gate insulation layer pattern 115a and a third conductive layer pattern 116b. When the gate insulation layer pattern 115a and the third conductive layer pattern 116b are formed using the second hard mask pattern as the etching mask according to an example embodiment of the present invention, etched by-products generated in the etching process may be greatly reduced in comparison with the conventional etching mask of the photoresist pattern. Thus, the second gate structure 117 may have substantially vertical sidewalls because an amount of the etched by-products attached to the sidewall of the second gate structure is small.

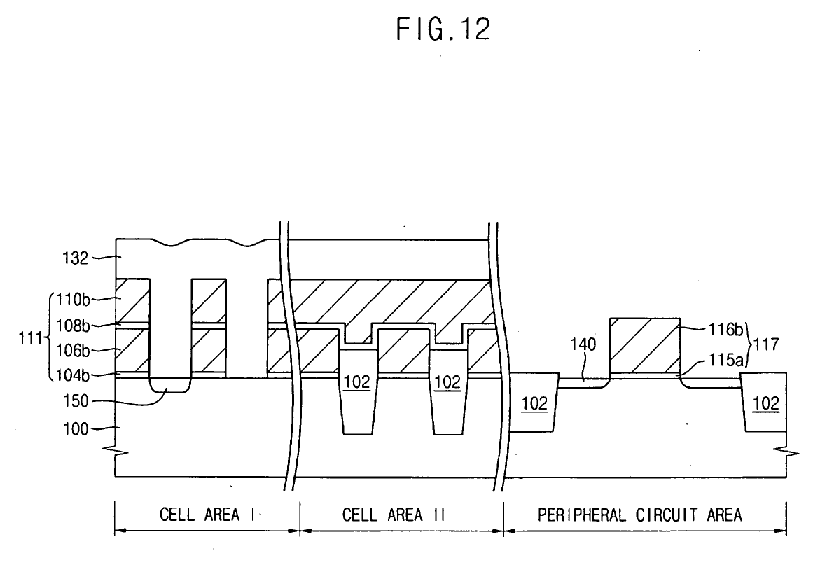

According to an example embodiment of the present invention as shown in FIG. 12, the second hard mask pattern 118b may be removed from the second gate structure 117 while the sixth photoresist pattern 132 may remain covering the cell area. Because the sixth photoresist pattern 132 may block the cell area in an etching process for removing the second hard mask 118b, the isolation layer patterns 102 and the dielectric layer pattern 108b in the cell area may not have any etched damages according to an example embodiment of the present invention.

In an example embodiment of the present invention, the second hard mask pattern 118b may be etched by, for example, a wet etching process. For example, the second hard mask pattern 118b may be removed using an etching solution including a hydrogen peroxide solution and an ammonia solution.

First impurities may be implanted into portions of the peripheral circuit area adjacent to the second gate structure 117 using the sixth photoresist pattern 132 and the second gate structure 117 as implantation masks. Hence, the second gate structure 117 may be doped with the impurities and first doping regions 140 having low impurity concentrations may be formed in the portions of the peripheral circuit area.

The sixth photoresist pattern 132 may be removed by, for example, an ashing process and/or a stripping process.

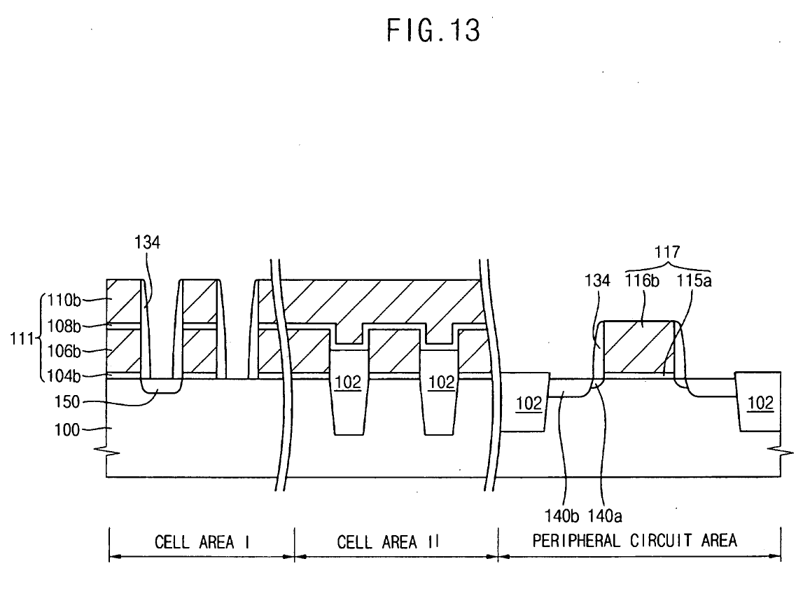

According to an example embodiment of the present invention as shown in FIG. 13, a silicon nitride layer (not shown) may be formed on the first gate structures 111, the second gate structure 117 and the semiconductor substrate 100. The silicon nitride layer may be anisotropically etched to form spacers 134 on sidewalls of the first and the second gate structures 111 and 117.

Second impurities may be implanted into the portions of the peripheral circuit area where the first doping regions 140a may be positioned to thereby form second doping regions 140b having high impurity concentrations. Accordingly, source/drain regions having the first and the second doping regions 140a and 140b may be formed adjacent to the second gate structure 117 in the peripheral circuit area

In an example embodiment of the present invention, a seventh photoresist pattern may be formed over the semiconductor substrate 100 to cover the cell area before forming the second doping regions 140b.

The spacers 134 may serve as blocking patterns that prevent silicidation of the sidewalls of the first and the second gate structures 111 and 117. Additionally, the spacers 134 may define the first doping regions 140a of the source/drain regions in the peripheral circuit area.

If each of the spacers 134 has a thickness of below about 300 Å, each of the first doping regions 140a may have a narrow width. When each of the spacers 134 has a thickness of above about 2,000 Å, each of the source/drain regions may have a narrow width so that contact areas between the source/drain regions and pads formed on the source/drain regions may be reduced. According to an example embodiment of the present invention, the spacers 134 may advantageously have thickness of between about 300 to about 2,000 Å.

Because the second gate structure 117 has substantially vertical sidewalls according to an example embodiment of the present invention, the spacer 134 on the sidewall of the second gate structure 117 may have a width substantially wider than that of the conventional spacer formed on the inclined sidewall of the conventional gate structure. Accordingly, the first doping regions 140a may have wider widths because the first doping regions 140a extend beneath the spacer 134 having the wide width.

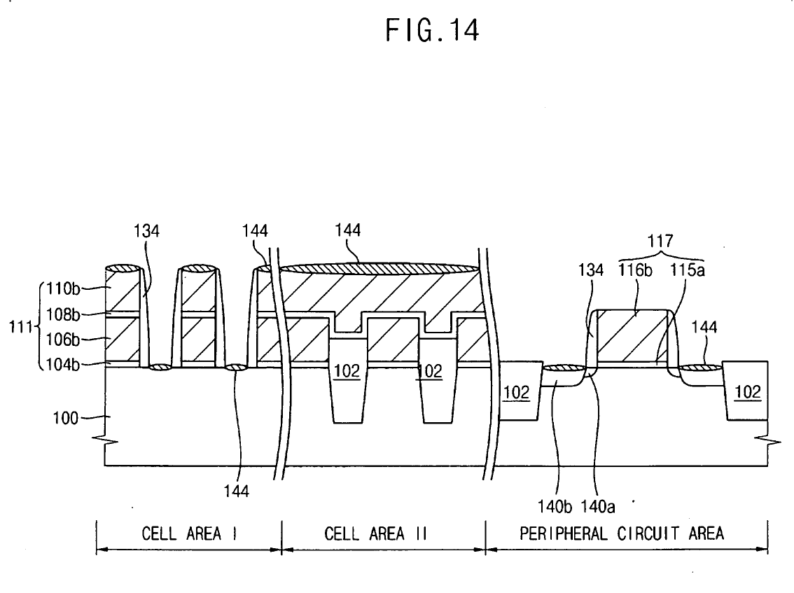

According to an example embodiment of the present invention as shown in FIG. 14, a metal layer (not shown) may be formed on the first gate structures 111, the second gate structure 117, the spacers 134 and the semiconductor substrate 100. The metal layer may be formed using, for example, cobalt, tungsten, titanium, tantalum, etc.

If a first thermal treatment process is performed on the semiconductor substrate 100, metal in the metal layer may be reacted with materials in the first gate structures 111, the second gate structure 117, the spacers 134 and the semiconductor substrate 100. Accordingly, preliminary metal silicide layers may be formed on the first gate structures 111, the second gate structure 117, the spacers 134 and the semiconductor substrate 100.

If a secondary thermal treatment process is performed on the preliminary metal silicide layers, the preliminary metal silicide layers may be converted into metal silicide layers that have stable phases. The second thermal treatment process may be executed at a second temperature substantially higher than a first temperature of the first thermal treatment process.

After the first and the second thermal treatment processes, metal silicide patterns 144 may be formed on the first gate structures 111, the source line 150, a drain region of the cell area, the second gate structure 117 and the second doping regions 140b. Because the metal layer may include cobalt, tungsten, titanium, tantalum, etc., the metal silicide patterns 144 may also include cobalt silicide, tungsten silicide, titanium silicide, tantalum silicide, etc.

If the metal silicide patterns 144 include cobalt silicide, the metal silicide patterns 144 may have low resistances even though the metal silicide patterns 144 have small areas because a resistance of cobalt silicide layer may not vary with respect to an area thereof. According to an example embodiment of the present invention, the metal silicide patterns 144 include cobalt silicide.

If the metal silicide patterns 144 include cobalt silicide, the first thermal treatment process may be performed at a first temperature of about 400 to about 500° C. Further, the first thermal treatment process may include a rapid thermal process (RTP). In the first thermal treatment process, the metal layer including cobalt may be reacted with silicon in the resultant structures to thereby form the preliminary metal silicide layer including cobalt mono-silicide (CoSi). The second thermal treatment process may be carried out at a second temperature of about 600 to about 900° C. The second thermal treatment process may also include a rapid thermal process. In the second thermal treatment process, the preliminary metal silicide layer including cobalt mono-silicide may be converted into the metal silicide layer including cobalt silicide (CoSi₂) that has a stable phase. Because the spacers 134 include silicon nitride according to an example embodiment of the present invention, the metal layers formed on the spacers 134 may not be silicided in the first and the second thermal treatment processes.

After the metal layers positioned on the spacers 134 are removed, a bit line B/L (see FIG. 15) may be formed to contact with the drain region of the cell transistor, and the non-volatile semiconductor memory device may be formed on the semiconductor substrate 100.

As described above according to example embodiments of the present invention, the second gate structure 117 in the peripheral circuit area has substantially vertical sidewalls. Accordingly, the spacer 134 formed on the substantially vertical sidewalls of the second gate structure 117 may have sufficiently wide widths so that the first doping regions 140a may also have sufficiently wide widths. Therefore, the transistor including the second gate structures 117 and the first doping regions 140a may have an improved breakdown voltage compared with conventional devices.

According to example embodiments of the present invention, a MOS transistor in a peripheral circuit area of a non-volatile semiconductor memory device may include a gate structure that has substantially vertical sidewalls through relatively simple manufacturing processes. Accordingly, the MOS transistor in the peripheral circuit area may have an enhanced breakdown voltage. Further, the MOS transistor in the peripheral circuit area may have improved response speed due at least in part to a metal silicide pattern having a low resistance, which may be formed on the gate structure and source/drain regions of the MOS transistor in the peripheral circuit area.

The foregoing example embodiments of the present invention are illustrative of the present invention and are not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention. In the claims, means-plus-function clauses are intended to cover the structures described herein as performing the recited function and not only structural equivalents. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

What is claimed is:

1. A method of manufacturing a non-volatile semiconductor memory device comprising:
forming a first gate structure in a first area of a substrate, the first gate structure including a tunnel oxide layer pattern, a first conductive layer pattern, a dielectric layer pattern and a second conductive layer pattern on the first area;
forming a first photoresist pattern on the second conductive layer pattern, the first photoresist pattern exposing a portion of the first area;
forming a second photoresist pattern on a hard mask layer;
forming a hard mask pattern on a third conductive layer by etching the hard mask layer using the second photoresist pattern as an etching mask; and
forming a second gate structure having substantially vertical sidewalls on a second area of the substrate by etching a third conductive layer using the hard mask pattern as an etching mask.

2. The method of claim 1, wherein forming the first gate structure includes:
sequentially forming a tunnel insulation layer, a preliminary first conductive layer pattern, a dielectric layer and a second conductive layer on the first area of the substrate; and
etching the second conductive layer, the dielectric layer, the preliminary first conductive layer and the tunnel insulation layer to form the second conductive layer pattern, the dielectric layer pattern, the first conductive layer pattern and the tunnel oxide layer pattern, respectively.

3. The method of claim 2, wherein forming the second gate structure includes:
sequentially forming a gate insulation layer and the third conductive layer on the second area of the substrate; and
etching the third conductive layer and the gate insulation layer using the hard mask pattern to provide a third conductive pattern and a gate insulation layer pattern, respectively.

4. The method of claim 1, further comprising:
forming a source line at the exposed portion of the first area by implanting impurities using the first photoresist pattern as a mask.

5. The method of claim 3, wherein the tunnel insulation layer, the preliminary first conductive layer pattern, the dielectric layer, the second conductive layer, the gate insulation layer, the third conductive layer and the hard mask layer are each simultaneously formed on both the first and the second areas of the substrate.

6. The method of claim 5, wherein sequentially forming the tunnel insulation layer, the preliminary first conductive layer pattern, the dielectric layer and the second conductive layer in the first area, and sequentially forming the gate insulation layer, the third conductive layer and the hard mask layer in the second area includes:
sequentially forming a preliminary tunnel insulation layer, a preliminary first conductive layer, a preliminary dielectric layer and a preliminary second conductive layer on the first and the second areas of the substrate;
forming the tunnel insulation layer, the preliminary first conductive layer pattern, the dielectric layer and the second conductive layer on the first area by etching portions of the preliminary tunnel insulation layer, the preliminary first conductive layer, the preliminary dielectric layer and the preliminary second conductive layer on the second area;
forming a preliminary gate insulation layer, a preliminary third conductive layer and a preliminary hard mask layer on the second conductive layer and on the second area; and
forming the gate insulation layer, the third conductive layer and the hard mask layer on the second area by selectively etching portions of the preliminary gate insulation layer, the preliminary third conductive layer and the preliminary hard mask layer positioned on the second conductive layer.

7. The method of claim 6, wherein the second conductive layer pattern and the third conductive layer comprises polysilicon.

8. The method of claim 1, wherein the first area corresponds to a cell area of the non-volatile semiconductor memory device and the second area corresponds to a peripheral circuit area of the non-volatile semiconductor memory device.

9. The method of claim 1, further comprising forming an isolation layer having a line shape on the first area, wherein the isolation layer extends along a direction substantially perpendicular to the second conductive layer pattern.

10. The method of claim 9, further comprising removing a portion of the isolation layer exposed by the first photoresist pattern prior to forming the source line.

11. The method of claim 10, wherein removing the portion of the isolation layer and forming the hard mask pattern are substantially, simultaneously performed.

12. The method of claim 1, further comprising:
forming an additional hard mask layer and an anti-reflective layer beneath the first and the second photoresist patterns.

13. The method of claim 12, wherein the additional hard mask layer comprises amorphous silicon.

14. The method of claim 1, further comprising:
forming a third photoresist pattern on the second conductive layer pattern to entirely cover the first area after forming the hard mask pattern.

15. The method of claim 14, further comprising:
removing the hard mask pattern remaining on the second gate structure;
forming spacers on sidewalls of the first and the second gate structures; and
forming metal silicide patterns on the first gate structure, the second gate structure and the substrate.

16. The method of claim 15, wherein removing the hard mask pattern is performed by a wet etching process using an etching solution that includes hydrogen peroxide solution and an ammonia solution.

17. The method of claim 15, wherein removing the hard mask pattern is performed after forming the third photoresist pattern.

18. The method of claim 15, wherein the spacers have a thickness within a range of about 300 to about 2,000 Å.

19. The method of claim 15, further comprising:
forming first doping regions having low impurity concentrations at portions of the second area adjacent to the second gate structure; and
removing the third photoresist pattern prior to forming the spacers.

20. The method of claim 15, wherein the metal silicide patterns comprise at least one of cobalt silicide, tungsten silicide, titanium silicide and tantalum silicide.

21. The method of claim 15, wherein forming the metal silicide patterns further comprises:
forming a metal layer on the first gate structure, the second gate structure, the spacers and the substrate;
forming the metal silicide patterns on the first gate structure, the second gate structure and the substrate by reacting metal in the metal layer with silicon in the first gate structure, the second gate structure and the substrate through at least one thermal treatment process; and
removing portions of the metal layer positioned on the spacers.

22. The method of claim 21, wherein the metal silicide patterns are formed by a first thermal treatment process at a first temperature and a second thermal treatment process at a second temperature substantially higher than the first temperature.

23. The method of claim 1, wherein the tunnel insulation layer and the gate insulation layer comprises silicon oxide, and the tunnel insulation layer has a thickness different from a thickness of the gate insulation layer.
